(19) United States
(12) Patent Application Publication
(10) Pub. No.: US 2018/0202043 A1
(43) Pub. Date: Jul. 19, 2018

(54) GAS SUPPLY SYSTEM, SUBSTRATE PROCESSING APPARATUS, AND METHOD OF MANUFACTURING SEMICONDUCTOR DEVICE

(71) Applicant: HITACHI KOKUSAI ELECTRIC INC., Tokyo (JP)

(72) Inventors: Takafumi SASAKI, Toyama-shi (JP); Daigi KAMIMURA, Toyama-shi (JP); Hidenari YOSHIDA, Toyama-shi (JP)

(73) Assignee: HITACHI KOKUSAI ELECTRIC INC., Tokyo (JP)

(21) Appl. No.: 15/923,796

(22) Filed: Mar. 16, 2018

Related U.S. Application Data
(63) Continuation of application No. PCT/JP2016/077235, filed on Sep. 15, 2016.

(30) Foreign Application Priority Data
Sep. 17, 2015 (JP) 2015-184131

(51) Int. Cl. C23C 16/455; H01L 21/02; C23C 16/458; C23C 16/34

(52) U.S. Cl. CPC C23C 16/45559; H01L 21/0217; C23C 16/345; C23C 16/4583; H01L 21/02271

(57) ABSTRACT

A gas supply system for improving concentration uniformity of a process gas supplied to substrates arrayed in a longitudinal direction includes first and second gas supply tubes that supply process gas from respective upper ends, and configured to supply the process gas for processing substrates to a process chamber that accommodates a plurality of the substrates arrayed in a longitudinal direction, wherein L1 is configured to be longer than L2 and S1 is configured to be smaller than S2, when the length of the first gas supply tube facing a substrate arrangement region where the substrates are arranged is L1, the flow path sectional area of the first gas supply tube is S1, the length of the second gas supply tube facing the substrate arrangement region is L2, and the flow path sectional area of the second gas supply tube is S2.

### TECHNICAL FIELD

This present disclosure relates to a substrate processing apparatus that processes a plurality of substrates held by a substrate holder and a method of manufacturing a semiconductor device.

### DESCRIPTION OF THE RELATED ART

In a vertical film-forming apparatus (see, for example, Patent Literature 1) that is one of substrate processing apparatuses, a boat (substrate holder) on which a plurality (several tens to hundreds) of substrates (wafers) is accommodated in a process chamber, a process gas is supplied and heated, the pressure and temperature of the process chamber are set to predetermined values, and film formation processing is performed on substrate surfaces.

In such a vertical film-forming apparatus, for example, a porous nozzle having gas ejection holes of the same number as the number of wafers is installed in a process chamber and used to supply a precursor gas to the wafers in the process chamber. When such a nozzle is used, vapor phase decomposition of the precursor gas proceeds inside the nozzle. Thermal decomposition in the vapor phase proceeds according to a residence time of being exposed to a decomposition temperature.

In the case of the porous nozzle, the residence time of the precursor gas is short at an upstream side of a gas flow (a lower stage side of a wafer arrangement region), and the residence time of the precursor gas is long at a downstream side (an upper stage side of the wafer arrangement region). Therefore, the precursor gas is ejected in an undecomposed state in the lower stage of the wafer arrangement region, and in a proceeding state of decomposition in the upper stage of the wafer arrangement region. A small amount of the precursor gas contributes to the film formation in the undecomposed state of the precursor gas, and a large amount of the precursor gas contributes to the film formation in the proceeding state of decomposition. Therefore, a difference in the film thickness is caused between upper wafers and lower wafers arrayed in the longitudinal direction. Specifically, the film thickness of the wafer on the upper stage side of the wafer arrangement region is thicker than the wafer on the lower stage side of the wafer arrangement region.

In addition to the method using the porous nozzle, there is also a method of disposing a plurality of open end nozzles having different lengths and supplying the precursor gas. Also in this case, the residence times of the precursor gas in the respective nozzles are different because the lengths of the nozzles are different. For example, between a gas passing through a long nozzle and a gas passing through a short nozzle, the gas passing through the long nozzle proceeds in thermal decomposition because of a long residence time, and the film thickness becomes thick in the upper stage of the wafer arrangement region, similarly to the porous nozzle.

### CITATION LIST

### Patent Literature

Patent Literature 1: JP 2008-95126 A

### SUMMARY

This present disclosure provides a structure for improving concentration uniformity of a process gas to be supplied to substrates arrayed in a longitudinal direction.

One aspect of this present disclosure provides a configuration including a gas supply system including a first gas supply tube and a second gas supply tube that supply process gases of a same kind at a same mass flow rate from respective upper ends, and configured to supply the process gas for processing a plurality of substrates to a process chamber that accommodates the plurality of substrates arrayed in a longitudinal direction via the first gas supply tube and the second gas supply tube, wherein L1 is configured to be longer than L2 and S1 is configured to be smaller than S2, when a length of the first gas supply tube facing a substrate arrangement region where the plurality of substrates is arranged is L1, a flow path sectional area of the first gas supply tube is S1, a length of the second gas supply tube facing the substrate arrangement region is L2, and a flow path sectional area of the second gas supply tube is S2.

### BRIEF DESCRIPTION OF DRAWINGS

FIG. 1 is a perspective view illustrating a substrate processing apparatus according to an embodiment of this present disclosure.

FIG. 2 is a schematic configuration view of a process furnace according to an embodiment of this present disclosure, and is a view illustrating a process furnace section in longitudinal section.

FIG. 3 is a sectional view taken along the line A-A of the process furnace illustrated in FIG. 2.

FIG. 4 is a diagram for describing a second gas supply system according to an embodiment of this present disclosure.

FIG. 5 is a view for describing a shape of a gas supply nozzle of a first example.

FIG. 6 is a view for describing a shape of a gas supply nozzle of a second example.

FIG. 7 is a block diagram for describing a controller of a substrate processing apparatus according to an embodiment of this present disclosure.

FIG. 8 is a view for describing a shape of a gas supply nozzle of a third example.

FIG. 9 is a view for describing a shape of a gas supply nozzle of a fourth example.

FIG. 10 is a diagram for describing an effect of the gas supply nozzle of the third example or the fourth example.

FIG. 11 is a diagram for describing an effect of the gas supply nozzle of the third example or the fourth example.

FIG. 12 is a diagram for describing an effect of the gas supply nozzle of the third example or the fourth example.

### DETAILED DESCRIPTION OF THE PREFERRED EMBODIMENTS

Hereinafter, a substrate processing apparatus in an embodiment of this present disclosure will be described with reference to the drawings. In the present embodiment, the substrate processing apparatus is configured as a semiconductor manufacturing apparatus that carries out a processing step in a method of manufacturing a semiconductor device, as an example. In the following embodiment, a case of applying a batch-type vertical semiconductor manufacturing apparatus (hereinafter also simply referred to as processing apparatus) that performs film formation processing such as CVD processing on substrates, as the substrate processing apparatus, will be described. Note that, in the following description, the same configuration elements are denoted by the same reference numeral, and repetitive description may be omitted. To make description clearer, the drawings may be schematically illustrated in the width, thickness, shape, etc. of each part as compared with an actual aspect. However, the illustration it is only an example and does not limit the construe of this present disclosure.

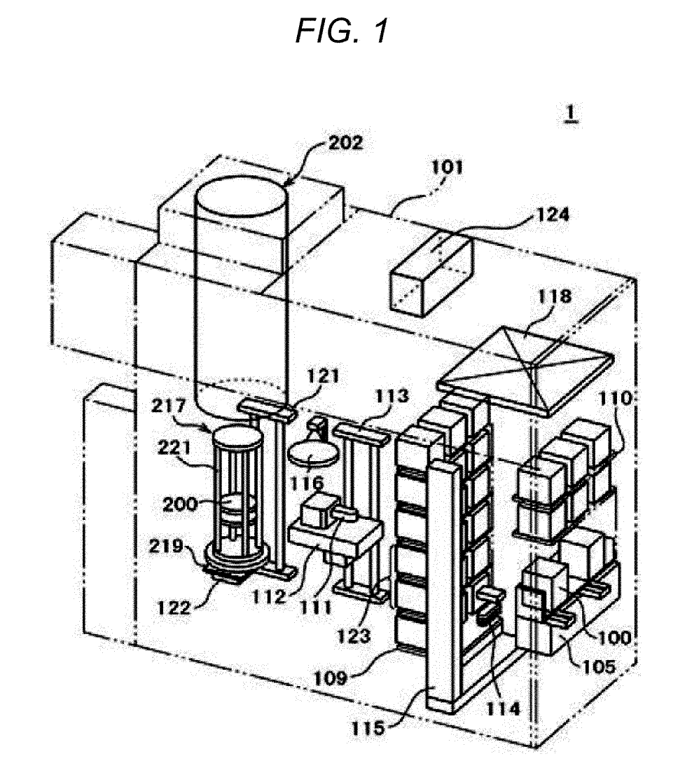

As illustrated in FIG. 1, a processing apparatus 1 using a cassette 100 as a wafer carrier that accommodates wafers (substrates) 200 includes a housing 101. A cassette stage 105 is installed in cassette loading/unloading opening (not illustrated) inside the housing 101. The cassette 100 is loaded onto the cassette stage 105 by an in-step transfer device (not illustrated) and is unloaded from the cassette stage 105.

The cassette stage 105 is placed such that the wafers 200 in the cassette 100 are in a vertical posture and a wafer loading/unloading port of the cassette 100 faces upward by the in-step transfer device. The cassette stage 105 is configured to be operable to rotate the cassette 100 clockwisely in the longitudinal direction by 90° toward the rear of the housing to make the wafers 200 in the cassette 100 are in a horizontal posture and the wafer loading/unloading port of the cassette 100 face the rear of the housing.

A cassette shelf 109 is installed in a substantially central portion in a front-rear direction in the housing 101, and the cassette shelf 109 is configured to store a plurality of the cassettes 100 in a plurality of rows and columns. The cassette shelf 109 is provided with a transfer shelf 123 in which the cassette 100 is stored. In addition, a spare cassette shelf 110 is provided above the cassette stage 105, and is configured to preliminarily store the cassette 100.

A cassette elevator 115 and a cassette transfer machine 114 capable of lifting while holding the cassette 100 are provided between the cassette stage 105 and the cassette shelf 109. The cassette elevator 115 and the cassette transfer machine 114 are configured to transfer, by its continuous operation, the cassette 100 among the cassette stage 105, the cassette shelf 109, and the spare cassette shelf 110.

A wafer transfer machine 112 capable of rotating or translating the wafers 200 in the horizontal direction and a transfer elevator 113 for lifting the wafer transfer machine 112 are provided in the rear of the cassette shelf 109. The transfer elevator 113 is installed in a right-side end portion of the pressure-resistant housing 101. The transfer elevator 113 and the wafer transfer machine 112 are configured to charge and discharge, by its continuous operation, the wafers 200 onto/from a boat (substrate retainer) 217, using a tweezer (substrate holding body) 111 of the wafer transfer machine 112 as a placement portion of the wafer 200.

A process furnace 202 is provided above and in a rear part of the housing 101. A lower end portion of the process furnace 202 is configured to be opened and closed with a furnace port shutter 116. A boat elevator 121 as a lift mechanism for lifting the boat 217 to the process furnace 202 is provided below the process furnace 202, a seal cap 219 as a lid is horizontally installed on a lift member 122 as a connecting tool connected to a lift of the boat elevator 121, and the seal cap 219 is configured to vertically support the boat 217 and to be able to block the lower end portion of the process furnace 202.

The boat 217 as substrate holding means includes a plurality of boat column parts 221, and is configured to horizontally hold a plurality of the wafers 200 (for example, about 50 to 150 wafers) in a state of aligning the wafers 200 in the vertical direction with their centers aligned.

As illustrated in FIG. 1, a clean unit 118 constituted by a supply fan and a dustproof filter to supply clean air which is a cleaned atmosphere is provided above the cassette shelf 109, and is configured to circulate clean air in the interior of the housing 101.

Next, an operation of the processing apparatus 1 will be described. As illustrated in FIG. 1, the cassette 100 is loaded through the cassette loading/unloading opening, and the wafers 200 are placed on the cassette stage 105 in the vertical posture and such that the wafer loading/unloading port of the cassette 100 faces upward. Thereafter, the cassette 100 is rotated clockwisely in the longitudinal direction by 90° toward the rear of the housing to make the wafers 200 in the cassette 100 in the horizontal posture and the wafer loading/unloading port of the cassette 100 face the rear of the housing by the cassette stage 105.

Next, the cassette 100 is automatically transferred to a designated shelf position of the cassette shelf 109 or the spare cassette shelf 110, passed, temporarily stored, and then transferred from the cassette shelf 109 or the spare cassette shelf 110 to the transfer shelf 123, or is directly transferred to the transfer shelf 123.

When the cassette 100 is transferred to the transfer shelf 123, the wafer 200 is picked up from the cassette 100 by the tweezer 111 of the wafer transfer machine 112 through the wafer loading/unloading port and charged in the boat 217. The wafer transfer machine 112 having transferred the wafer 200 to the boat 217 returns to the cassette 100 and charges the next wafer 200 into the boat 217.

When the number of wafers 200 designated in advance is charged on the boat 217, the lower end portion of the process furnace 202 closed with the furnace port shutter 116 is opened with the furnace port shutter 116. Next, the boat 217 holding the wafer 200 group is loaded into the process furnace 202 as the seal cap 219 is lifted by the boat elevator 121.

After the loading, arbitrary processing is performed for the wafers 200 in the process furnace 202. After the processing, the wafers 200 and the cassette 100 are carried out to an outside of the housing 101 by a reverse procedure from the above-described procedure.

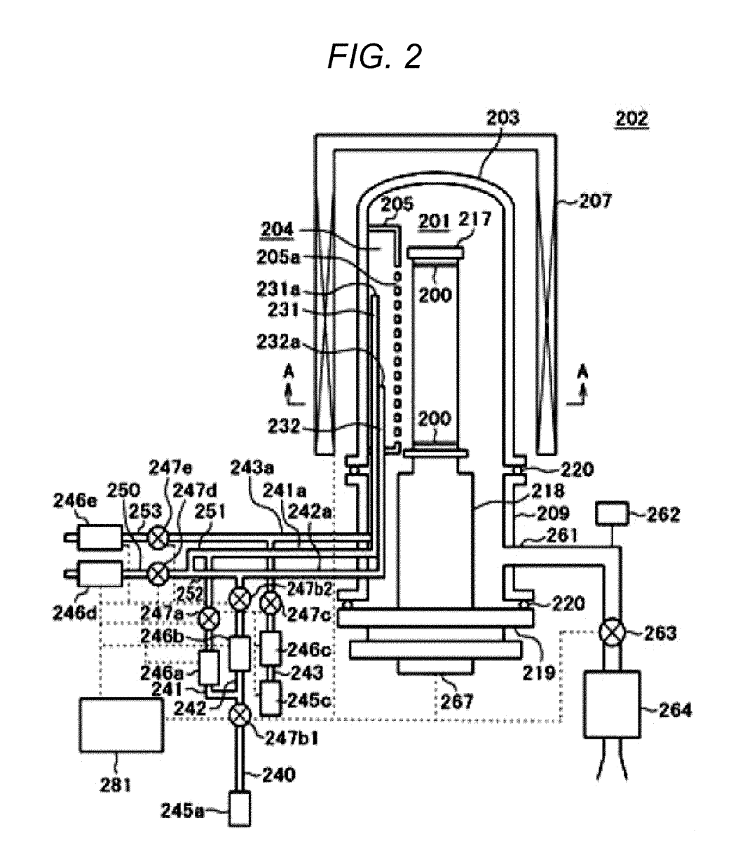

Next, the above-described process furnace 202 will be described in detail with reference to FIGS. 2 to 4.

As illustrated in FIG. 2, a reaction tube 203 as a reaction container for processing the wafers 200 as substrates is provided inside a heater 207 as a heating device (heating section). A manifold 209 is provided in a lower end of the reaction tube 203 via an O-ring 220 as an airtight member. A lower end opening of the manifold 209 is airtightly blocked with the seal cap 219 as a lid via the O-ring 220.

At least a process chamber (reaction chamber) 201 is formed by the reaction tube 203, the manifold 209, and the seal cap 219. The material of the reaction tube 203 is, for example, quartz. The material of the manifold 209 and the seal cap 219 is, for example, stainless steel.

The boat 217 as a substrate holding member (substrate retainer) is erected on the seal cap 219 via a boat support base 218. The boat support base 218 serves as a holding body for holding the boat. Then, the boat 217 is inserted into the process chamber 201. In the boat 217, the plurality of wafers 200, which is to undergo batch processing, is stacked in the horizontal posture in multiple stages in a tube axis direction of the reaction tube 203. In this manner, the boat 217 holds the plurality of wafers 200 arrayed in the longitudinal direction (vertical direction).

Note that, in FIG. 2, only the wafers 200 mounted in uppermost and lowermost stages of the boat 217 are illustrated. However, a plurality of the wafers 200 is also held between the uppermost and lowermost wafers 200. In addition, in FIG. 2, illustration of the boat columns 221 is omitted for easy understanding of the drawing.

The heater 207 is provided around the reaction tube 203 and heats the wafers 200 inserted in the process chamber 201 to a predetermined temperature. In the example of FIG. 2, the heater 207 is provided to surround a wafer arrangement region (substrate arrangement region) where the plurality of wafers 200 is arranged. Specifically, the heater 207 is provided to cover the reaction tube 203 above a boundary between a bottom portion of the boat 217 and an upper portion of the boat support base 218. Further, the heater 207 is provided to cover a buffer chamber 204 described later. A temperature sensor 265 (not illustrated) for measuring the temperature of the wafers 200 is provided inside or outside the reaction tube 203.

The buffer chamber 204 for supplying a process gas at a uniform flow rate to the plurality of wafers 200 on the boat 217 is provided inside the reaction tube 203. The material of a buffer chamber wall 205 forming the buffer chamber 204 is, for example, quartz. The buffer chamber 204 is a space surrounded by the buffer chamber wall 205 and a side wall of the reaction tube 203, and is provided to face the plurality of wafers 200 on the boat 217. A nozzle 231 and a nozzle 232 having a tube axis in the longitudinal direction are arranged in a stacking direction (longitudinal direction) of the plurality of wafers 200 in the buffer chamber 204. The nozzles 231 and 232 configure a first gas supply system to be described later. Therefore, the process gas inside the nozzles 231 and 232 extending upward in the wafer arrangement region surrounded by the heater 207 proceed in decomposition by heat of the heater 207.

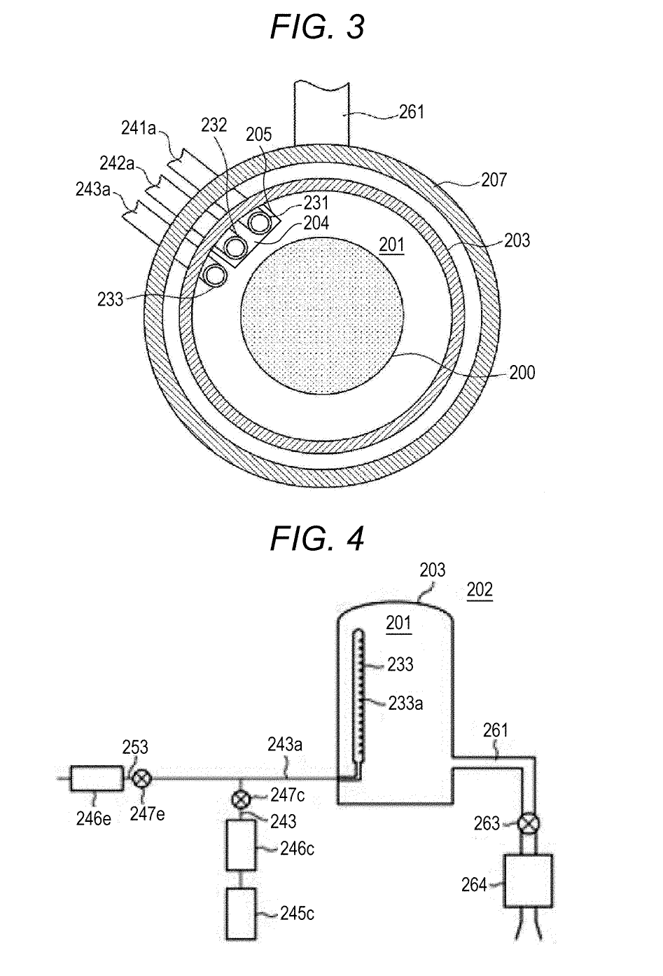

Further, as illustrated in FIGS. 3 and 4, a nozzle 233 configuring a second gas supply system to be described later is arranged inside the reaction tube 203 and outside the buffer chamber 204. The nozzle 233 is a porous nozzle having a plurality of gas outlets 233a in its side wall. The nozzles 231 to 233 are bent at right angle in the vicinity of the manifold 209 to change its directions in the horizontal direction, pass through the manifold 209 from an inside to an outside, and are then connected to gas piping 241a to 243a. The material of the nozzles 231 to 233 is, for example, quartz.

Note that joints between the nozzles 231 to 233 and the gas piping 241a to 243a may be formed inside the manifold 209. In this case, the gas piping 241a to 243a pass through the manifold 209 from an outside to an inside, are then bent at right angle in the vicinity of the manifold 209 to change its directions in the vertical direction, and are connected to the nozzles 231 to 233.

In FIG. 2, the nozzle 231 is drawn at a more distant position than the nozzle 232 with respect to the boat 217 for easy understanding of the drawing. However, as illustrated in FIG. 3, the nozzles 231 and 232 are favorably arranged at an equal distance with respect to the boat 217. In addition, openings to be described later are provided in upper ends of the nozzles 231 and 232, and the process gas is supplied into the buffer chamber 204 through the openings. In the present embodiment, the gas is supplied from the two nozzles 231 and 232. However, needless to say, the number of nozzles is not limited to the number (two).

Further, as illustrated in FIG. 3, one porous nozzle 233 is disposed outside the buffer chamber 204. However, a plurality of the nozzles 233 configuring the second gas supply system may be arranged inside the buffer chamber 204. In this case, a plurality of the gas outlets 233a of the plurality of nozzles 233 is not provided as illustrated in FIG. 4, and one opening may be provided upward in an upper end of the nozzle 233, like the nozzles 231 and 232.

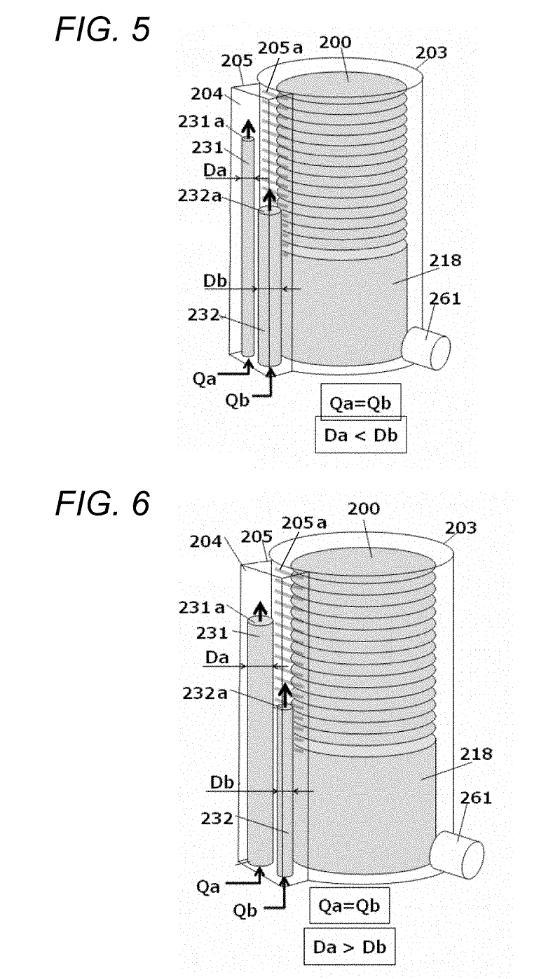

As illustrated in FIG. 2, the buffer chamber 204 is disposed inside the reaction tube 203. However, the buffer chamber 204 may be arranged outside the reaction tube 203. In first to four examples described later, the buffer chamber 204 is arranged outside the reaction tube 203 (see FIGS. 5, 6, 8, and 9).

As a supply path for supplying a plurality of types (two types in the embodiment) of process gases to the process chamber 201, two gas supply systems (a first gas supply system and a second gas supply system) are provided as a gas supply mechanism.

(First Gas Supply System) The first gas supply system for supplying a precursor gas (first process gas) to the process chamber 201 will be described in detail with reference to FIGS. 2 and 3. The first gas supply system includes a first gas supply line and a first carrier gas supply line.

The first gas supply line includes a first gas source 245a as a precursor supplier for supplying a precursor and a valve 247b1 as an on-off valve in order from an upstream direction in the gas piping 240 that supplies the first process gas, and is branched to a gas piping 241 and a gas piping 242 at a downstream side of the valve 247b1 (at a downstream side of a gas flow). Hereinafter, the on-off valve may be referred to as valve.

A mass flow controller (MFC) 246a as a flow rate control device (flow rate control section) and a valve 247a are provided in order from an upstream direction in the gas piping 241. The gas piping 241 joins a gas piping 251, that is, the first carrier gas supply line to be described later at a downstream side of the valve 247a to become as the gas piping 241a. Hereinafter, the mass flow controller may be referred to as MFC. The mass flow controller performs flow rate control by measuring a mass flow rate of the gas.

An MFC 246b and a valve 247b2 are provided in order from an upstream direction in the gas piping 242. The gas piping 242 joins a gas piping 252, that is, the first carrier gas supply line at a downstream side of the valve 247b2 to become the gas piping 242a.

The first carrier gas supply line includes an MFC 246d and a valve 247d in order from an upstream direction in a gas piping 250 that supplies a carrier gas. The gas piping 250 is branched to the gas piping 251 and the gas piping 252 at a downstream side of the valve 247d. As described above, the gas piping 251 and the gas piping 252 join the gas piping 241 and the gas piping 242 respectively to become the gas piping 241a and the gas piping 242a.

The nozzles 231 and 232 are attached to tip end portions on a downstream side of the gas piping 241a and 242a, respectively. The nozzles 231 and 232 extend in the buffer chamber 204 from a lower part to an upper part of the buffer chamber 204 and are provided along the stacking direction (longitudinal direction) of the wafers 200.

A gas outlet 231a as an opening through which a gas is ejected from the nozzle 231 into the buffer chamber 204 is open upward and provided in an upper end of the nozzle 231. Further, a gas outlet 232a as an opening through which a gas is ejected from the nozzle 232 into the buffer chamber 204 is open upward and provided in an upper end of the nozzle 232. Since the gas outlets 231a and 232a are open upward, the gases output from the nozzles 231 and 232 are ejected upward, respectively.

Note that the gas outlet 231a in the upper end of the nozzle 231 and the gas outlet 232a in the upper end of the nozzle 232 may be configured to open in a direction other than upward, such as a direction opposite to the direction of the wafers 200 (a direction of the reaction tube 203), or a cross direction (a direction along a tube wall of the reaction tube 203). In doing so, in a case where the flow rate of the gas is large, the momentum in the upward direction of the gasses ejected from the nozzles 231 and 232 can be suppressed, and the amount of gas flowing out from an upper portion of the buffer chamber 204 being larger than the amount of gas flowing out from a lower portion can be suppressed.

As illustrated in FIG. 2, the gas outlet 231a is provided at a position about ¾ or less from the bottom in the region (wafer arrangement region) where the plurality of wafers 200 on the boat 217 is arranged. The gas outlet 232a is provided at a position about ¼ or less from the bottom in the wafer arrangement region. Specifically, in a case where the directions of the gas outlets 231a and 232a are upward, the gas outlets 231a and 232a are provided at a position slightly lower than about ¾ from the bottom and a position slightly lower than about ¼ from the bottom, respectively, and in a case where the directions of the gas outlets 231a and 232a are opposite to the direction of the wafers 200 or the cross direction, the gas outlets 231a and 232a are provided at a position about ¾ from the bottom and a position about ¼ from the bottom, respectively. In this way, the nozzles 231 and 232 are provided at positions having the same distance from the center (position ½ from the bottom) of the wafer arrangement region.

In this way, the length of the nozzle 231 facing the wafer arrangement region is longer than the length of the nozzle 232 facing the wafer arrangement region. With the configuration, the flow velocities of the gases to be supplied to the process chamber 201 through the plurality of gas outlets 205a of the buffer chamber 204 can be made the same, and supply of the process gas at a uniform flow rate from the buffer chamber 204 to the plurality of wafers 200 on the boat 217 is facilitated. Here, making the flow velocities or flow rates of the gases the same includes not only a case where the flow velocities or flow rates are strictly the same but also a case where the process gases supplied to the wafers 200 perform processing of similar extent.

The plurality of gas outlets 205a for ejecting the gas in the buffer chamber 204 into the process chamber 201 is provided in a surface of the buffer chamber wall 205, the surface facing the boat 217, as a plurality of openings communicating with the process chamber 201. The gas outlets 205a are provided at positions facing the arrangement region of the plurality of wafers 200.

Further, as illustrated in FIG. 2, the plurality of gas outlets 205a is favorably provided to correspond to the wafers 200 on a one-to-one basis, to be specific, provided to correspond to positions between the wafer 200 and the wafer 200. Thereby, supply of the process gas at a uniform flow rate to the plurality of wafers 200 on the boat 217 is facilitated.

In this manner, the first process gas passes through the gas piping 240 from the first gas source 245a and is branched into the gas piping 241 and the gas piping 242 at the downstream side of the valve 247b1. The flow rate of the process gas in the gas piping 241 is adjusted by the MFC 246a, and the process gas joins the carrier gas supplied from the gas piping 251 via the valve 247a. Then, the first process gas having joined the carrier gas from the gas piping 251 passes through the gas piping 241a, is supplied to the buffer chamber 204 through the gas outlet 231a formed in the nozzle 231, and is supplied to the process chamber 201 through the gas outlet 205a formed in the buffer chamber 204.

Further, the flow rate of the process gas in the gas piping 242 is adjusted by the MFC 246b, and the process gas joins the carrier gas supplied from the gas piping 252 via the valve 247b 2. Then, the first process gas having joined the carrier gas from the gas piping 252 passes through the gas piping 242a, is supplied to the buffer chamber 204 through the gas outlet 232a formed in the nozzle 232, and is supplied to the process chamber 201 through the gas outlet 205a formed in the buffer chamber 204. Here, the buffer chamber 204 may also be included in the first gas supply system.

(Second Gas Supply System) Next, the second gas supply system for supplying a second process gas to react with the first process gas to the process chamber 201 will be described in detail with reference to FIGS. 2 to 4. The second gas supply system is configured by a second gas supply line and a second carrier gas supply line.

As illustrated in FIG. 2, the second gas supply line is configured to include a second gas source 245c, an MFC 246c, and a valve 247c in order from an upstream direction in a gas piping 243 that supplies the second process gas.

The second carrier gas supply line is configured to include an MFC 246e and a valve 247e in order from an upstream direction in a gas piping 253 that supplies the carrier gas. The gas piping 243 of the second gas supply line and the gas piping 253 of the second carrier gas supply line join each other at a downstream side of the valve 247c and the valve 247e to become the gas piping 243a. The nozzle 233 is attached to a tip end portion of the gas piping 243a on a downstream side.

As illustrated in FIGS. 3 and 4, the nozzle 233 is formed in an arc space between an inner wall of the reaction tube 203 configuring the process chamber 201 and the wafers 200 in the stacking direction (longitudinal direction) of the wafers 200 along the inner wall from a lower portion to an upper portion of the reaction tube 203. In this manner, the nozzle 233 is arranged along the stacking direction of the plurality of wafers 200 on the boat 217.

The plurality of gas outlets 233a as supply holes for supplying a gas to the process chamber 201 is provided in the side surface of the nozzle 233 to face the wafers 200 in the region where the plurality of wafers 200 on the boat 217 exists. The gas outlets 233a have the same opening area from the lower portion to the upper portion and are further provided at the same opening pitch. The gas outlets 233a have a hole diameter of 0.1 to 5 mm, for example, and are favorably provided to correspond to the wafers 200 on a one-to-one basis. Thereby, supply of the process gas at a uniform flow rate to the plurality of wafers 200 on the boat 217 is facilitated.

In this manner, the second process gas passes through the gas piping 243 from the second gas source 245c, the flow rate of which is adjusted by the MFC 246c, and the second process gas joins the carrier gas supplied from the gas piping 253 via the valve 247c. Then, the gas passes through the gas piping 243a and is supplied to the process chamber 201 through the gas outlets 233a formed in the third nozzle 233.

Next, characteristics of the gas supply mechanism of the present embodiment will be described in detail with reference to FIGS. 5 and 6 and FIGS. 8 and 9. In FIGS. 5 and 6 and FIGS. 8 and 9, illustration of the boat 217 is omitted.

In FIGS. 5 and 6 and FIGS. 8 and 9, the buffer chamber 204 is provided outside the reaction tube 203. However, the buffer chamber 204 may be provided inside the reaction tube 203 as described above. Further, the buffer chamber 204 is provided up to the bottom of the boat support base 218. However, as illustrated in FIG. 2, the buffer chamber 204 may be provided up to the upper portion of the boat support base 218.

(First Example) As illustrated in FIG. 5, two tip end (upper end) open gas supply nozzles 231 and 232 having different lengths and diameters are installed in a buffer chamber 204 arranged on a side of wafers 200. The buffer chamber 204 communicates with a process chamber 201 through gas outlets 205a. In the example of FIG. 5, the gas outlets 205a are slits long and narrow in the cross direction and provided on a one-to-one basis with respect to the wafers 200. However, the gas outlet 205a may be a circular hole. An inner diameter Da of the long nozzle 231 is narrower than an inner diameter Db of the short nozzle 232. For example, Da is 10 to 15 mm and Db is 20 to 25 mm.

If the mass flow rate of the gas passing through the gas outlet 205a of the buffer chamber 204 differs in the up and down direction, the flow velocity of the gas passing over the wafer 200 differs between the upper and lower wafers 200, and inter-surface film thickness distribution may differ between the upper wafer 200 and the lower wafer 200 (the inter-surface film thickness distribution differs from top to bottom). Therefore, it is desirable to provide a precursor gas of the same kind at the same mass flow rate to the nozzles 231 and 232 (Qa=Qb). Qa is the mass flow rate of a first gas flowing in the nozzle 231, and Qb is the mass flow rate of the first gas flowing in the nozzle 232. Qa=Qb is realized by making the mass flow rates of the gases flowing in MFCs 246a and 246b the same. Note that the mass flow rates being the same in this specification include not only a case where mass flow rates are strictly the same but also a case where values of Qa and Qb are close to the extent that the difference in the degree of inter-surface processing (for example, the film thickness distribution) between the wafers 200 can be suppressed.

The nozzle 231 is longer than the nozzle 232, and thus in a case where the nozzles 231 and 232 have the same sectional area, the residence time of the gas passing through the nozzle 231 is longer than the residence time of the gas passing through the nozzle 232. Therefore, the gas in the nozzle 231 is heated by the heater 207 for a longer time than the gas in the nozzle 232, and thus vapor phase decomposition of the precursor gas in a gas outlet 231a of the nozzle 231 proceeds further than vapor phase decomposition of the precursor gas in a gas outlet 232a of the nozzle 232.

To solve this problem, as illustrated in FIG. 5, the inner diameter Da of the long nozzle 231 is made smaller than the inner diameter Db of the short nozzle 232, and the flow velocity of gas in the nozzle 231 is increased. Thereby, the residence time of the gas in the nozzle 231 heated by the heater 207 is adjusted to be the same as the residence time of the gas in the nozzle 232 heated by the heater 207. That is, the residence time of the gas in the nozzle 231 facing a wafer arrangement region where the wafers 200 are arranged is adjusted to be the same as the residence time of the gas in the nozzle 232 facing the wafer arrangement region.

That is, L1 is set to be longer than L2 and S1 is set to be smaller than S2, when the length of the nozzle 231 facing the wafer arrangement region where the wafers 200 are arranged is L1, a flow path sectional area is S1, the length of the nozzle 232 facing the wafer arrangement region is L2, and a flow path sectional area is S2.

In doing so, when the precursor gases inside the nozzles 231 and 232 are decomposed by the heat from the heater 207 and are generated as a process gas that contributes to wafer processing, the degrees of decomposition of the precursor gases at the nozzle outlets of the nozzles 231 and 232 are uniform. Therefore, the concentration of the precursor gas is the same at the outlet 231a of the nozzle 231 and at the outlet 232a of the nozzle 232. Therefore, the concentration of the precursor gas of when the precursor gas is supplied into the process chamber 201 through the plurality of gas outlets 205a is the same in the wafer arrangement region where the wafers 200 are arranged. Note that, in the present specification, the concentrations of the precursor gas being the same includes not only a case where concentrations are strictly the same but also a case where values of the concentration of a film-forming gas are close to the extent that the difference in the inter-surface film thickness distribution between the wafers 200 can be suppressed.

In this manner, deviation of the concentration distribution of the precursor gas in the longitudinal direction of the wafers 200 is reduced, and flat inter-surface film thickness distribution can be obtained. The example of FIG. 5 is suitable for a case of the pressure in the process chamber 201 in which a pressure loss in each nozzle is relatively small and does not reach a choke flow, that is, for an environment in which the pressure in the process chamber 201 is 100 Pa or more as a first predetermined pressure (for example, an environment of 100 to 10000 Pa).

(Second Example) Next, characteristics of a gas supplier of a second example will be described with reference to FIG. 6. In an environment in which the pressure inside a process chamber 201 is less than 100 Pa (for example, in an environment of 1 to 50 Pa), an interior of a tip end open gas supply nozzle has a choke flow, and the gas flow velocity passing through the nozzle becomes a sound velocity determined by an ambient temperature without depending on the nozzle sectional area. In this case, even if the sectional areas are made different as illustrated in FIG. 5, the flow velocity in the nozzle is constant (sound velocity). Therefore, the residence time of the gas in a nozzle 231 becomes longer than that in a nozzle 232, and decomposition of a precursor gas in the nozzle 231 is further promoted.

Therefore, as illustrated in FIG. 6, the sectional area of the nozzle 231 is made larger than the sectional area of the nozzle 232. In the example of FIG. 6, an inner diameter Da (for example, 23 mm) of the long nozzle 231 is larger than an inner diameter Db (for example, 13 mm) of the short nozzle 232. Only this point is different from the example of FIG. 5, the other points are the same as the example of FIG. 5.

That is, L1 is set to be longer than L2 and S1 is set to be larger than S2, when the length of the nozzle 231 facing a wafer arrangement region where wafers 200 are arranged is L1, a flow path sectional area is S1, the length of the nozzle 232 facing the wafer arrangement region is L2, and a flow path sectional area is S2.

By doing so, although the flow paths of the nozzles 231 and 232 still have the sound speed due to the choke flow, the nozzles 231 and 232 maintain the same mass flow rate (Qa=Qb), and thus an internal pressure of the nozzle 231 having the large sectional area becomes low. This is because the mass flow rate (kg/s)=(the nozzle sectional area (m²))×(the gas density (kg/m³))×(the flow velocity (sound velocity) (m/s)), and thus the gas density (that is, the internal pressure) becomes small when the nozzle sectional area is large.

Decomposition of a precursor gas is influenced by an environmental pressure in addition to the temperature and the residence time. Specifically, in a high-pressure field, the decomposition reaction is facilitated due to a high frequency of collision between molecules, and vice versa in a low pressure field. As described above, since the internal pressure of the nozzle 231 having a large sectional area becomes low, the decomposition of the precursor gas is suppressed. In this way, in an extremely low pressure environment of less than 100 Pa (in particular, less than 50 Pa as a second predetermined pressure), decomposition states of the precursor gas at nozzle outlets can be made uniform by the reverse setting (Da>Db) to that in the first example, and film thickness distribution of the wafers 200 can be flattened from top to bottom of a boat 217.

In a case where the pressure in the process chamber 201 is a pressure in a transition region between the first predetermined pressure and the second predetermined pressure (for example, in an environment of 50 to 100 Pa), the decomposition states of the precursor gas at the nozzle outlets can be made the same by setting Da=Db. Note that Da and Db may be set to slightly satisfy Da>Db.

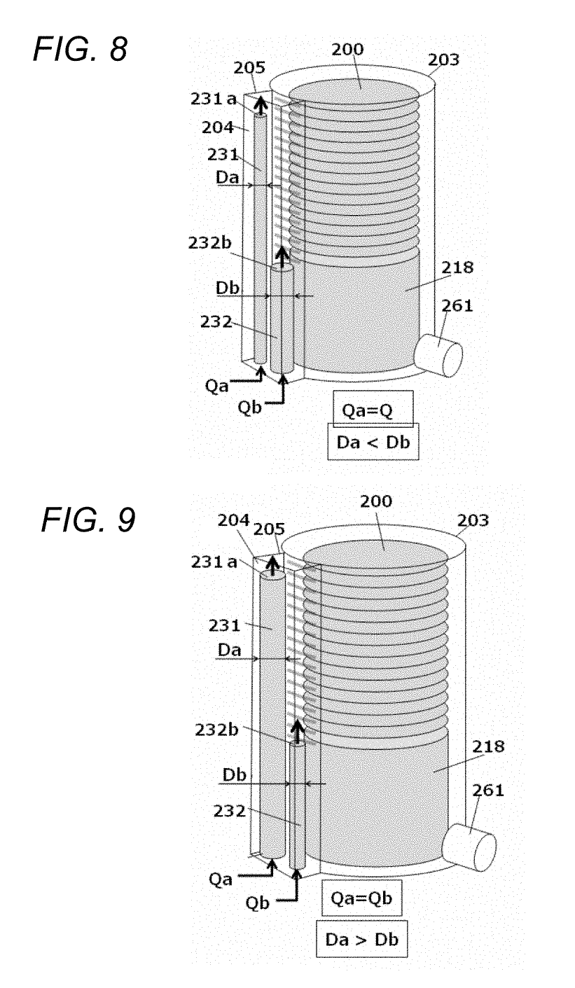

(Third Example and Fourth Example) FIG. 8 illustrates a third example as an improved configuration of the first example, and FIG. 9 illustrates a fourth example as an improved configuration of the second example. Comparing the first example with the third example, and the second example with the fourth example, lengths of respective nozzles are merely changed and other configurations are the same, and thus detailed description is omitted. The difference in the lengths of the respective nozzles will be described later.

In recent years, to increase the degree of integration of semiconductor devices, miniaturization and 3D structuring of integrated circuit patterns have been in progress, and the surface area of the wafer 200 has been steadily increased accordingly. Thereafter, such a wafer 200 may be referred to as processed wafer (patterned wafer). Since a precursor gas consumption speed per unit time is increased as the surface area of the wafer is increased, the precursor gas concentration on the surface of the processed wafer 200 tends to be decreased. Therefore, the film thickness of the processed wafer 200 becomes thinner as the precursor gas concentration is decreased, and thus favorably keeping the concentration uniformity of the precursor gas in a substrate arrangement region is difficult.

In the substrate processing apparatus 1 in the present embodiment, several wafers in upper and lower stages in the substrate arrangement region are processed as bare wafers (dummy wafers) in processing the patterned wafers 200. At this time, since the consumption of the precursor gas is large in the region (substrate processing region) of the processed wafers 200, the precursor gas concentration is decreased. Meanwhile, in bare wafer regions where the dummy wafers are arranged, the concentration is high due to an excess precursor gas. That is, since concentration diffusion occurs through a gap between a wafer edge portion (end portion) and an inner wall of a reaction tube, high and low concentration of the precursor gas occurs in a wafer stacking direction. In this case, the concentration distribution in a height direction of the processed wafer 200 region does not become uniform, and the concentration uniformity of the process gas in the substrate arrangement region is deteriorated. Since the film thickness is increased/decreased according to the high and low concentration of the precursor gas, film thickness uniformity (inter-surface uniformity) in the height direction of the processed wafer 200 region is deteriorated.

In the third example illustrated in FIG. 8 (or the fourth example illustrated in FIG. 9), nozzles 231 and 232 are installed such that an outlet 231a of the nozzle 231 and an outlet 232a of the nozzle 232 face the bare wafer regions. Thereby, the concentration uniformity of the precursor gas in the up and down direction of the substrate arrangement region can be made uniform in processing the patterned wafers 200.

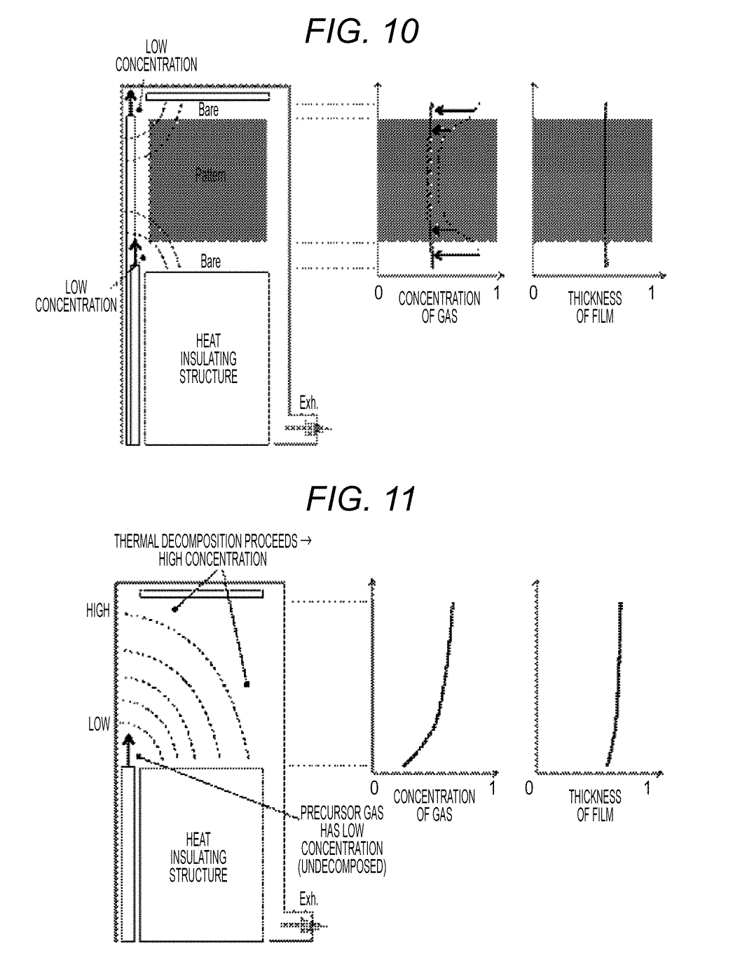

FIG. 10 illustrates concentration distribution and film thickness distribution of the precursor gas of when the nozzles 231 and 232 are installed such that the outlet 231a of the nozzle 231 and the outlet 232a of the nozzle 232 illustrated in the third example (or in the fourth example) face the bare wafer regions. Thereby, the concentration uniformity of the precursor gas in the substrate processing region can be made favorable in processing the patterned wafers 200. Therefore, the inter-surface uniformity of the film thickness can be made favorable.

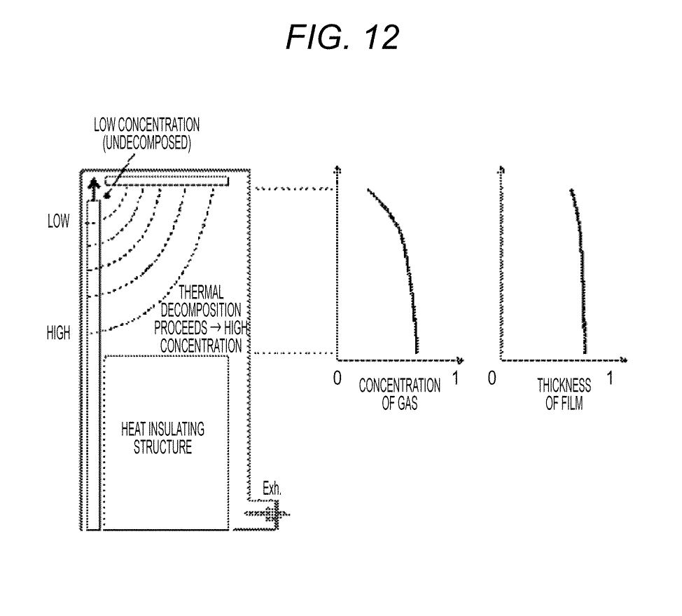

FIG. 11 or 12 is a diagram for describing the concentration distribution and the film thickness distribution of the precursor gas illustrated in FIG. 10. In FIGS. 10 to 12, precursor gas supply nozzles are provided in a reaction tube 203, and a buffer chamber 204 is deleted for easy understanding the description.

FIG. 11 illustrates a state of the concentration distribution of the precursor gas of when a precursor gas supply nozzle 231 (232) is short. For example, in a case where a hexachlorodisilane (Si2Cl6, abbreviation: HCDS) gas is used as a Si source gas as the precursor gas, the HCDS gas is thermally decomposed, and an Si radical gas such as SiCl2 is generated. Generally, since the Si radical gas has a high adhesion probability to the surface of the wafer 200, the high and low concentration of this gas is considered to correlate with the increase and decrease in the film thickness. In a case where the precursor gas supply nozzle 231 (232) is short, a large amount of undecomposed gas is supplied to the lower stage side of the wafers 200. Therefore, the concentration of the Si radical gas is low and the film thickness becomes thin. Meanwhile, thermal decomposition of the precursor gas proceeds on the upper stage side of the substrate arrangement region. Therefore, the Si radical gas is abundantly present, and the film thickness becomes thick.

FIG. 12 similarly illustrates a state of the concentration distribution of the HCDS gas of when the precursor gas supply nozzle 231 (232) is long. In this case, the film thickness distribution is opposite to the film thickness distribution state illustrated in FIG. 11.

That is, the precursor gas supply nozzle 231 or 232 illustrated in FIG. 10 has film thickness distribution in which the behaviors described in FIGS. 11 and 12 are offset. The outlet 231a of the nozzle 231 and the outlet 232a of the nozzle 232 are positioned to face the bare wafer regions, whereby the Si radical concentration in the upper and lower stages of the substrate arrangement region (or the substrate processing region) can be decreased, and the precursor gas concentration distribution can be made uniform in the height direction of the substrate arrangement region (or the substrate processing region). Thereby, the film thickness distribution in the substrate processing region becomes uniform, and the inter-surface uniformity of the film thickness distribution is improved.

Further, the outlet 231a of the nozzle 231 and the outlet 232a of the nozzle 232 may be provided at boundaries between the substrate processing region and the bare wafer regions. Further, the outlet 231a of the nozzle 231 and the outlet 232a of the nozzle 232 may be arranged at positions facing the substrate processing region. Note that, in this case, the outlet 231a of the nozzle 231 and the outlet 232a of the nozzle 232 are favorably arranged at positions of about several number of the processed wafers 200 from the upper and lower bare wafer regions and at positions having the same distance from the center of the substrate processing region.

Although not specifically described, in the third and fourth examples, the decomposition of the precursor gas is influenced not only by the temperature and the residence time but also by the environmental pressure, similarly to the first and second examples. In short, in a high-pressure field, the decomposition reaction is facilitated due to a high frequency of collision between molecules, and vice versa in a low pressure field.

Although not specifically described, in the third and fourth examples, the internal pressure of the nozzle 231 having a large sectional area is low, and thus the decomposition of the precursor gas is suppressed. In an extremely low pressure environment of less than 100 Pa (in particular, less than 50 Pa as a second predetermined pressure), decomposition states of the precursor gas at nozzle outlets can be made uniform by the reverse setting (Da>Db) to that in the third example, as described in the fourth example, and the film thickness distribution of the wafers 200 can be flattened from top to bottom of a boat 217.

Although not specifically described, in the third and fourth examples, in a case where the pressure in a process chamber 201 is a pressure in a transition region (for example, in an environment of 50 to 100 Pa), decomposition states of the precursor gas at the nozzle outlets can be made the same by setting Da=Db, similarly to the first and second examples. Further, similarly, Da and Db may be set to slightly satisfy Da>Db.

As illustrated in FIG. 2, the process chamber 201 is connected to a vacuum pump 264 as an exhaust device (exhaust means) via an APC valve 263 with an exhaust pipe 261 as an exhaust pipe for exhausting a gas, and is vacuum-exhausted. The exhaust pipe 261 is provided with a pressure sensor 262 for measuring the pressure inside the process chamber 201. The APC valve 263 is an on-off valve that can open and close a valve to vacuum-exhaust the process chamber 201 and stop vacuum exhaust, and can further adjust the pressure by adjusting the degree of valve opening. The degree of valve opening of the APC valve 263 is controlled by a controller 281 described later on the basis of the value of the pressure sensor 262.

As illustrated in FIG. 2, the boat 217 that holds the plurality of wafers 200 at the same intervals in multiple stages is provided in the central portion of the reaction tube 203. The boat 217 can enter and leave the reaction tube 203 by the boat elevator 121 (see FIG. 1). Further, to improve uniformity of processing, a boat rotation mechanism 267 for rotating the boat 217 is provided, and the boat 217 supported by the boat support base 218 is rotated as the boat rotation mechanism 267 is driven.

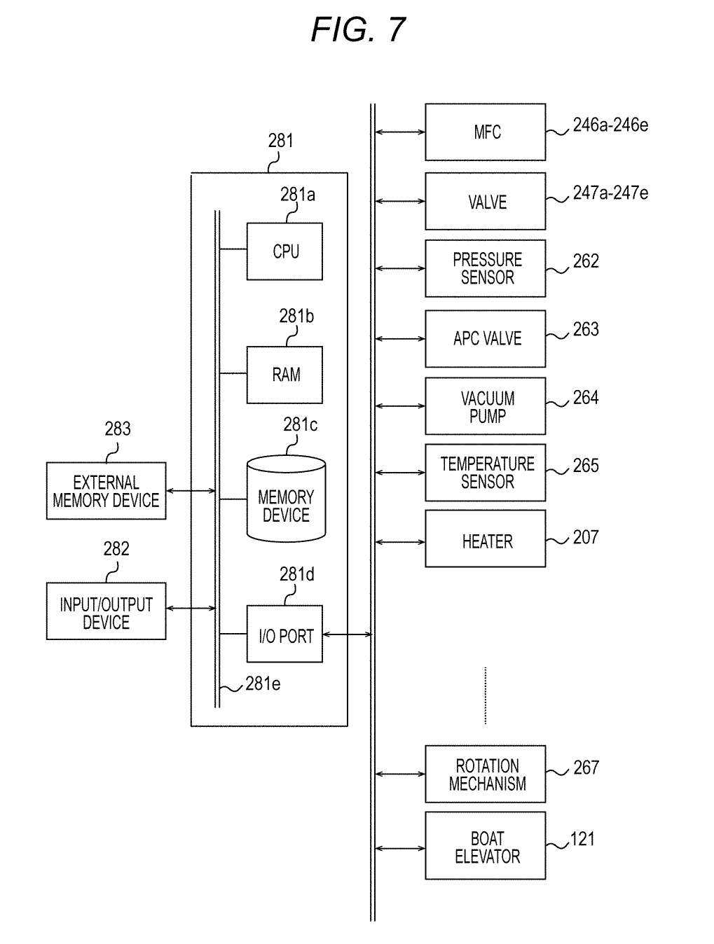

Next, a controller as a control section (control means) will be described with reference to FIG. 7.

As illustrated in FIG. 7, the controller 281 is configured as a computer including a central processing unit (CPU) 281a, a random access memory (RAM) 281b, a memory device 281c, and an I/O port 281d. The RAM 281b, the memory device 281c, and the I/O port 281d are configured to exchange data with the CPU 281a via an internal bus 281e. An input/output device 282 configured as, for example, a touch panel is connected to the controller 281.

The memory device 281c is configured by, for example, a flash memory and a hard disk drive (HDD). In the memory device 281c, a control program for controlling the operation of the substrate processing apparatus, a process recipe and the like in which procedures and conditions of substrate processing described later are described, are readably stored. Note that the process recipe is combined to cause the controller 281 to execute procedures in a substrate processing step described later to obtain a predetermined result. Further, the RAM 281b is configured as a memory area (work area) in which programs, data, and the like read by the CPU 281a are temporarily stored.

The I/O port 281d is connected to the MFCs 246a to 246e, the valves 247a to 247e, the pressure sensor 262, the APC valve 263, the vacuum pump 264, the heater 207, the rotation mechanism 267, the boat elevator 121, and the like.

The CPU 281a is configured to read the control program from the memory device 281c and executes the control program, and read the process recipe from the memory device 281c in response to an input of an operation command from the input/output device 282. Then, the CPU 281a is configured to control flow rate adjustment operations of various gases by the MFCs 246a to 246e, open and close operations of the valves 247a to 247e, an open and close operation of the APC valve 263, a pressure adjustment operation of the APC valve 263 based on the pressure sensor 262, a temperature adjustment operation of the heater 207 based on the temperature sensor 265, start and stop of the vacuum pump 264, rotation and a rotation speed adjustment operation of the boat 217 by the rotation mechanism 267, a lift operation of the boat 217 by the boat elevator 121, and the like in accordance with content of the read process recipe.

Note that the controller 281 is not limited to the configuration as a dedicated computer, and may be configured as a general-purpose computer. For example, the controller 281 according to the example can be configured by installing a program in a general-purpose computer using the external memory device 283 that stores the above-described program.

The memory device 281c and the external memory device 283 are configured as computer-readable recording media. Hereinafter, the computer-readable recording media are collectively and simply referred to as recording medium. In the present specification, the term “recording medium” may include only the memory device 281c alone, only the external memory device 283 alone, or both.

Note that the means for supplying the program to the computer is not limited to the case of supplying the computer via the external memory device 283. For example, the program may be supplied using communication means such as the Internet or a dedicated line without going through the external memory device 283.

Next, as a step of manufacturing a semiconductor device (device) using the above-described substrate processing apparatus 1, a sequence example of processing for forming a film on a substrate (hereinafter also referred to as film formation processing) will be described. Here, an example of forming a film on the wafer 200 by alternately supplying, to the wafer 200 as the substrate, the first process gas as the precursor gas and the second process gas as the reactant gas to chemically react with a precursor gas component deposited on the wafer 200 will be described.

Hereinafter, an example of forming a silicon nitride film (Si₃N₄ film, hereinafter also referred to as SiN film) on the wafer 200, using the HCDS gas as the precursor gas and an ammonia (NH₃) gas as the reactant gas will be described. In the following description, the operations of the units that configure the substrate processing apparatus 1 are controlled by the controller 281.

In film formation processing in the present embodiment, a SiN film is formed on each of the wafers 200 by performing a predetermined number of times (once or more times) of cycles of non-simultaneously performing a step of supplying the HCDS gas to the wafers 200 in the process chamber 201, a step of removing the HCDS gas (residual gas) from the interior of the process chamber 201, a step of supplying the NH₃ gas to the wafers 200 in the process chamber 201, and a step of removing the NH₃ gas (residual gas) from the interior of the process chamber 201.

In the present specification, the term “wafer” means a wafer itself, or a laminate of a wafer and a predetermined layer or film formed on the surface of the wafer in some cases. In the present specification, the term “surface of a wafer” means a surface of a wafer itself, or a surface of a predetermined layer or the like formed on the wafer in some cases. In the present specification, the phrase “forming a predetermined layer on a wafer” means directly forming a predetermined layer on a surface of a wafer itself, or forming a predetermined layer on a layer or the like formed on the wafer. In the present specification, the term “substrate” is synonymous with the word “wafer”.

When a plurality of wafers 200 is charged in the boat 217, the boat 217 is loaded into the process chamber 201 by the boat elevator 121. At this time, the seal cap 219 is in a state of airtightly blocking the lower end of the reaction tube 203 via the O-ring 220.

The vacuum pump 264 performs vacuum exhaust (decompression exhaust) such that the interior of the process chamber 201, that is, a space where the wafers 200 exist, has a predetermined pressure (the degree of vacuum). At this time, the pressure inside the process chamber 201 is measured by the pressure sensor 262, and the APC valve 263 is feedback-controlled on the basis of the measured pressure information. The vacuum pump 264 maintains an operating state on a steady basis at least until the processing for the wafers 200 is completed.

The wafers 200 in the process chamber 201 are heated by the heater 207 so as to have a predetermined temperature. At this time, the degree of energization to the heater 207 is feedback-controlled on the basis of temperature information detected by the temperature sensor 265 such that the process chamber 201 has a predetermined temperature distribution. Heating in the process chamber 201 by the heater 207 is continuously performed at least until processing on the wafers 200 is completed.

Further, rotation of the boat 217 and the wafers 200 by the rotation mechanism 267 is started. The wafers 200 are rotated as the boat 217 is rotated by the rotation mechanism 267. The rotation of the boat 217 and the wafers 200 by the rotation mechanism 267 is continuously performed at least until the processing for the wafers 200 is completed.

When the temperature inside the process chamber 201 becomes stable at a preset processing temperature, the following two steps, that is, steps 1 and 2 are sequentially executed.

(Step 1) In this step, the HCDS gas is supplied to the wafers 200 in the process chamber 201. The valves 247b1, 247a, and 247b2 are opened to allow the HCDS gas to flow into the gas piping 240. The HCDS gas is branched into the gas piping 241 and the gas piping 242. The flow rate of the HCDS gas in the gas piping 241 is adjusted by the MFC 246a, and the HCDS gas is supplied from the gas piping 241a into the process chamber 201 via the nozzle 231 and the buffer chamber 204, and is exhausted through the exhaust pipe 261. Further, the flow rate of the HCDS gas in the gas piping 242 is adjusted by the MFC 246b, and the HCDS gas is supplied from the gas piping 242a into the process chamber 201 via the nozzle 232 and the buffer chamber 204, and is exhausted through the exhaust pipe 261.

In this manner, the HCDS gas is supplied to the wafers 200 in the process chamber 201 through the nozzles 231 and 232 via the buffer chamber 204. At this time, the mass flow rates of the HCDS gases supplied through the nozzles 231 and 232 are controlled to be the same by the MFC 246a and the MFC 246b.

When supplying the HCDS gas, the valve 247d is opened to allow the N₂ gas into the gas piping 251 and into the gas piping 252. The flow rate of the N₂ gas is adjusted by the MFC 246d, and the N₂ gas is supplied together with the HCDS gas into the process chamber 201, and is exhausted through the exhaust pipe 261. By supplying the HCDS gas to the wafer 200, a Si-containing layer is formed as a first layer on an outermost surface of the wafer 200.

After the formation of the first layer, the valves 247b1, 247a and 247b2 are closed to stop the supply of the HCDS gas. At this time, with the APC valve 263 open, the interior of the process chamber 201 is vacuum-exhausted by the vacuum pump 264, and the HCDS gas which remains in the process chamber 201, is unreacted, or has contributed to formation of the first layer is discharged from the interior of the process chamber 201. At this time, the supply of the N₂ gas into the process chamber 201 is maintained with the valve 247d open. The N₂ gas acts as a purge gas, and an effect of discharging the gas remaining in the process chamber 201 from the interior of the process chamber 201 can be thereby enhanced.

At this time, the gas remaining in the process chamber 201 is not necessarily completely discharged, and the interior of the process chamber 201 is not necessarily completely purged. If the amount of the gas remaining in the process chamber 201 is very small, no adverse effect will be caused in step 2 that is subsequently performed. The flow rate of the N₂ gas to be supplied into the process chamber 201 is not necessarily a high flow rate, and for example, purge not to cause the adverse influence can be performed in step 2 by supplying the N₂ gas of an amount approximately equal to the volume of the reaction tube 203 (the process chamber 201). The purge time can be shortened and the throughput can be improved by not completely purging the interior of the process chamber 201. The consumption of N₂ gas can also be minimized.

(Step 2) After step 1 is completed, the NH₃ gas is supplied to the wafers 200 in the process chamber 201, that is, to the first layers formed on the wafers 200. The NH₃ gas is activated by heat and is supplied to the wafers 200.

In this step, the flow rate of the NH₃ gas is adjusted by the MFC 246c, the NH₃ gas is supplied from the gas piping 243 into the process chamber 201 via the gas piping 243a and the nozzle 233, and is exhausted through the exhaust pipe 261. At this time, the NH₃ gas is supplied to the wafers 200. When supplying the NH₃ gas, the valve 247e may be opened at the same time to allow the N₂ gas to flow into the gas piping 253. The flow rate of the N₂ gas is adjusted by the MFC 246e and the N₂ gas is supplied into the process chamber 201 together with the NH₃ gas.

The NH₃ gas supplied to the wafers 200 reacts with the first layers formed on the wafers 200 in step 1, that is, at least a part of the Si-containing layers. Thereby, the first layer is thermally nitrided with non-plasma and is changed (modified) to a second layer containing Si and N, that is, a SiN layer. At this time, the first layer may be changed to the second layer by supplying the plasma-excited NH₃ gas to the wafers 200 and plasma nitriding the first layer.

After the formation of the second layer, the valve 247c is closed to stop the supply of the NH₃ gas. Then, by a similar processing procedure to step 1, the valves 247d and 247e are opened to supply the N₂ gas into the nozzles 231 to 233, and the NH₃ gas which remains in the process chamber 201, which is unreacted, or which has contributed to formation of the second layer, or reaction by-products are discharged from the interior of the process chamber 201. At this time, similarly to step 1, it is not necessary to completely discharge the gas or the like remaining in the process chamber 201.

An SiN film having a predetermined composition and a predetermined film thickness can be formed on each of the wafers 200 by performing a predetermined number of times (n times) of cycles of non-simultaneously performing the above-described two steps, that is, without causing the two steps in synchronization with each other. That is, the thickness of the second layer formed when the above-described cycle is performed once is made smaller than a predetermined film thickness, and the above-described cycle is repeated a plurality of times until the film thickness of the SiN film formed by laminating the second layer to be a predetermined film thickness.

Processing conditions for the film formation processing include, for example, the processing temperature (wafer temperature): 250 to 800° C., the processing pressure (the pressure in the process chamber): 1 to 4000 Pa, the HCDS gas supply flow rate: 1 to 2000 sccm, the NH₃ gas supply flow rate: 100 to 10000 sccm, and the N₂ gas supply flow rate (at the time of supplying the HCDS gas): 100 to 10000 sccm. By setting each processing condition to a certain value within each range, the film formation processing can appropriately proceed.

For example, in a case where the processing pressure is 100 to 150 Pa, the processing temperature is set to 500 to 630° C. and the nozzles illustrated in FIG. 5 (first example) are used as the nozzles 231 and 232. In a case where the processing pressure is 5 to 20 Pa, the processing temperature is set to 500 to 630° C. and the nozzles illustrated in FIG. 6 (second example) are used as the nozzles 231 and 232. Further, in a case of the patterned wafer 200, the nozzles illustrated in FIG. 8 (third example) or the nozzles illustrated in FIG. 9 (fourth example) are used as the nozzles 231 and 232 according to the processing pressure.

In either case, when supplying the HCDS gas, the HCDS gas at 100 sccm is supplied to the nozzles 231 and 232. At the same time, the N₂ gas at the flow rate of 0 to 500 sccm is supplied to the nozzles 231 and 232, and the N₂ gas at 100 sccm is supplied to the nozzle 233. The reason why the N₂ gas is supplied to the nozzle 233 is to prevent intrusion of the HCDS gas.

In addition, when supplying the NH₃ gas after the supply of the HCDS gas is finished, the NH₃ gas at 5000 sccm is supplied to the nozzle 233. At the same time, the N₂ gas at the flow rate of 0 to 10000 sccm is supplied to the nozzle 233, and the N₂ gas at 500 sccm is supplied to the nozzles 231 and 232. The reason why the N₂ gas is supplied to the nozzles 231 and 232 is to prevent the intrusion of the NH₃ gas.

After the film formation processing is completed, the valve 247d is opened to supply the N₂ gas from the gas piping 251 and the gas piping 252 into the process chamber 201 via the buffer chamber 204, the N₂ gas is exhausted through the exhaust pipe 261. The N₂ gas acts as a purge gas. As a result, the interior of the process chamber 201 is purged, and the gas remaining in the process chamber 201 and reaction by-products are removed from the interior of the process chamber 201. Note that, at the time of purging, the valve 247e may be opened to supply the N₂ gas into the process chamber 201 from the gas piping 253 via the gas piping 243a and the nozzle 233. Thereafter, the atmosphere in the process chamber 201 is replaced with an inert gas (N₂ gas) (inert gas replacement), and the pressure in the process chamber 201 is returned to a normal pressure (return to atmospheric pressure).

The seal cap 219 is lowered by the boat elevator 121, and the lower end of the reaction tube 203 is opened. Then, the processed wafers 200 are unloaded from the lower end of the reaction tube 203 to the outside of the reaction tube 203 in a state of being supported by the boat 217. The processed wafers 200 are taken out from the boat 217.

Note that, in the above-described embodiment, the step of supplying the HCDS gas and the step of supplying the N₂ gas are non-simultaneously performed. However, this present disclosure is not limited thereto, and is applicable to a process of simultaneously performing the two steps.

As described above, according to the present embodiment, once or more of the following effects (1) to (6) can be obtained.

(1) In the gas supply mechanism including the first gas supply tube and the second gas supply tube that supply the process gas of a same kind at a same mass flow rate from the respective upper ends, L1 can be configured to be longer than L2 and S1 can be configured to be smaller than S2, when the length of the first gas supply tube facing a substrate arrangement region is L1 and the flow path sectional area is S1, and the length of the second gas supply tube facing the substrate arrangement region is L2 and the flow path sectional area is S2. Therefore, the concentration uniformity of the process gas to be supplied to the plurality of substrates arranged in the substrate arrangement region can be improved.

(2) A buffer chamber that accommodates the first gas supply tube and the second gas supply tube, and has a plurality of openings communicating with the process chamber is included, and the process gases supplied from the first gas supply tube and the second gas supply tube are configured to be supplied to the process chamber through the plurality of openings at the same flow velocity. Therefore, the concentration uniformity of the process gas to be supplied to the substrates can be further improved.

(3) The plurality of openings in the buffer chamber is configured to be provided in positions facing the substrate arrangement region. Therefore, the concentration uniformity of the process gas to be supplied to the substrates can be further improved.

(4) The plurality of openings in the buffer chamber can be configured to correspond to the plurality of substrates, respectively. Therefore, the concentration uniformity of the process gas to be supplied to the substrates can be further improved.

(5) In the gas supply mechanism including the first gas supply tube and the second gas supply tube that supply the process gas of a same kind at a same mass flow rate from the respective upper ends, L1 can be configured to be longer than L2 and S1 can be configured to be smaller than S2, or L1 can be configured to be longer than L2 and S1 can be configured to be larger than S2, or L1 can be configured to be longer than L2 and S1 and S2 can be configured to be equal, when the length of the first gas supply tube facing a substrate arrangement region is L1 and the flow path sectional area is S1, and the length of the second gas supply tube facing the substrate arrangement region is L2 and the flow path sectional area is S2, according to the pressure in the process chamber. Therefore, the concentration uniformity of the process gas to be supplied to the plurality of substrates arranged in the substrate arrangement region can be improved.

(6) In the gas supplier including the first gas supply tube and the second gas supply tube that supply the process gas of a same kind at a same mass flow rate from the respective upper ends, the respective upper ends of the first gas supply tube and the second gas supply tube are arranged at positions facing a bare wafer region, whereby the concentration uniformity of the process gas between substrates with patterns arranged in the process chamber can be improved.

The above-described effects can be similarly obtained in a case where a gas other than the HCDS gas is used as the precursor gas, in a case where a gas other than the NH₃ gas is used as the N-containing gas, or in a case where an inert gas other than the N₂ gas is used as the purge gas.

It is needless to say that this present disclosure is not limited to the above embodiment, and various modifications can be made without departing from the gist of this present disclosure.

In the above embodiment, it has been configured that the HCDS gas is supplied from the first gas supply system. However, this present disclosure is not limited thereto. For example, it can be configured that a monosilane gas (SiH₄ gas) is supplied from the first gas supply system. For example, the monosilane gases of 50 to 250 sccm are supplied to the process chamber at 100 to 150 Pa and around 700° C. through the nozzles 231 and 232 in FIG. 5, respectively.

In the above embodiment, the gas supply system that supplies the process gas to the process chamber has been configured to include the first gas supply system and the second gas supply system. However, this present disclosure is not limited thereto, and this present disclosure is also applicable to a case where the gas supply system is configured by only the first gas supply system.

Further, in the above embodiment, the buffer chamber 204 has been provided and the nozzles 231 and 232 have been disposed in the buffer chamber 204. However, it can be configured that the buffer chamber 204 is not provided and the nozzles 231 and 232 are arranged in the reaction tube 203 depending on process conditions (the process gas type, the pressure, the temperature, the degree of requirement for the film thickness uniformity, and the like).

This present disclosure is applicable not only to a semiconductor manufacturing apparatus but also to an apparatus for processing a glass substrate such as an LCD manufacturing apparatus and other substrate processing apparatuses. In the above embodiment, the film formation of the nitride film has been described as an example. However, the film type is not particularly limited, and this present disclosure is applicable to various film types such as an oxide film (SiO or the like) and a metal oxide film. Further, this present disclosure is also applicable to substrate processing other than the film formation processing.

This application claims the benefit of priority based on Japanese Patent Application No. 2015-184131 filed on Sep. 17, 2015, the disclosure of which is incorporated herein by reference in its entirety.

### INDUSTRIAL APPLICABILITY

This present disclosure is applied to a substrate processing apparatus that supplies a process gas to substrates loaded in a substrate holder to process the substrates.

### REFERENCE SIGNS LIST

1 Substrate processing apparatus
200 Substrate (wafer)
201 Process chamber
207 Heater
217 Boat (substrate holder)
231 Nozzle
231a Gas outlet
232 Nozzle
232a Gas outlet
281 Control section (controller)

1. A gas supply system comprising: a first gas supply tube and a second gas supply tube that supply process gases of a same kind at a same mass flow rate from respective upper ends, and configured to supply the process gas for processing a plurality of substrates to a process chamber that accommodates the plurality of substrates arrayed in a longitudinal direction via the first gas supply tube and the second gas supply tube, wherein L1 is configured to be longer than L2 and S1 is configured to be smaller than S2, when a length of the first gas supply tube facing a substrate arrangement region where the plurality of substrates is arranged is L1, a flow path sectional area of the first gas supply tube is S1, a length of the second gas supply tube facing the substrate arrangement region is L2, and a flow path sectional area of the second gas supply tube is S2.

2. The gas supply system according to claim 1, further comprising: a buffer chamber that accommodates the first gas supply tube and the second gas supply tube, and includes a plurality of openings communicating with the process chamber, wherein the process gases supplied from the first gas supply tube and the second gas supply tube are configured to be supplied to the process chamber through the plurality of openings.

3. The gas supply system according to claim 2, wherein the plurality of openings is provided in positions facing the substrate arrangement region, and flow velocities of the gases to be supplied to the process chamber through the plurality of openings are configured to be the same.

4. The gas supply system according to claim 3, wherein a first time during which the gas flows in an interior of the first gas supply tube facing the substrates and a second time during which the gas flows in an interior of the second gas supply tube facing the substrates are configured to be the same.

5. A substrate processing apparatus comprising: a process chamber that accommodates a plurality of substrates arrayed in a longitudinal direction; a gas supply system including a first gas supply tube and a second gas supply tube that supply process gases for processing the plurality of substrates from respective upper ends to the process chamber; and a control section configured to control a flow rate of the process gas to be supplied to the process chamber via the gas supply system , wherein, in the gas supply system , L1 is configured to be longer than L2 and S1 is configured to be smaller than S2, when a length of the first gas supply tube facing a substrate arrangement region where the plurality of substrates is arranged is L1, a flow path sectional area of the first gas supply tube is S1, a length of the second gas supply tube facing the substrate arrangement region is L2, and a flow path sectional area of the second gas supply tube is S2, and the control section controls the process gases to be supplied to the first gas supply tube and to the second gas supply tube to be of a same kind at a same mass flow rate.

6. The substrate processing apparatus according to claim 5, further comprising: a buffer chamber that accommodates the first gas supply tube and the second gas supply tube, and includes a plurality of openings communicating with the process chamber, wherein the process gases supplied from the first gas supply tube and the second gas supply tube are configured to be supplied to the process chamber through the plurality of openings.

7. The substrate processing apparatus according to claim 5, wherein, when a pressure in the process chamber is a second predetermined pressure or more and less than a first predetermined pressure, the flow path sectional area of the first gas supply tube and the flow path sectional area of the second gas supply tube are configured to be the same.

8. The substrate processing apparatus according to claim 5, wherein, when a pressure in the process chamber is a first predetermined pressure or more, the gas supplier is configured to have the flow path sectional area of the first gas supply tube smaller than the flow path sectional area of the second gas supply tube.

9. The substrate processing apparatus according to claim 5, wherein, when a pressure in the process chamber is less than a second predetermined pressure, the gas supplier is configured to have the flow path sectional area of the first gas supply tube larger than the flow path sectional area of the second gas supply tube.

10. The substrate processing apparatus according to claim 5, further comprising: a heating section configured to heat the substrate arrangement region, wherein precursor gases in interiors of the first gas supply tube and the second gas supply tube are decomposed by the heating section and generated as the process gases that contribute to substrate processing, and concentrations of the process gases when the process gases are supplied through the plurality of openings to the process chamber are configured to be the same in an up and down direction of the substrate arrangement region.

11. The substrate processing apparatus according to claim 5, wherein the substrate arrangement region is separated into a substrate processing region and bare wafer regions where patterned substrates are arranged, and the upper ends of the first gas supply tube and the second gas supply tube are configured to be arranged at positions facing the bare wafer regions.

12. A method of manufacturing a semiconductor device, the method comprising: supplying process gases of a same kind at a same mass flow rate for processing a plurality of substrates arrayed in a longitudinal direction from respective upper ends of a first gas supply tube and a second gas supply tube to the substrate arrangement region to process the plurality of substrates, wherein L1 is configured to be longer than L2 and S1 is configured to be smaller than S2, when a length of the first gas supply tube facing a substrate arrangement region in which the plurality of substrates is arranged is L1, a flow path sectional area is S1, a length of the second gas supply tube facing the substrate arrangement region is L2, and a flow path sectional area is S2.
